(19) United States
(12) Patent Application Publication
(10) Pub. No.: US 2025/0168985 A1
(43) Pub. Date: May 22, 2025

(54) CIRCUIT BOARD AND METHOD FOR MOUNTING ELECTRONIC COMPONENT

(71) Applicant: Panasonic Intellectual Property Management Co., Ltd., Osaka (JP)

(72) Inventors: Toshiharu MOTOFUSA, Kyoto (JP); Shohei YAMANAKA, Osaka (JP)

(73) Assignee: Panasonic Intellectual Property Management Co., Ltd., Osaka (JP)

(21) Appl. No.: 18/839,673

(22) PCT Filed: Jan. 27, 2023
(86) PCT No.: PCT/JP2023/002671

§ 371 Date: Aug. 19, 2024

(30) Foreign Application Priority Data
Feb. 24, 2022 (JP) 2022-027264

(51) Int. Cl. H05K 1/18; H01L 23/00; H05K 1/11; H05K 3/34; H10D 80/20

(52) U.S. Cl. CPC H05K 1/181; H05K 1/111; H05K 3/341; H05K 3/3485; H01L 24/48; H01L 2224/48091; H01L 2224/48245; H01L 2924/13091; H05K 2201/10166; H05K 2201/10757; H10D 80/251

(57) ABSTRACT

A circuit board includes an electronic component and a printed wiring board to which the electronic component is mounted by soldering. The electronic component includes a pad electrode disposed at a bottom portion of a body part. The pad electrode has a leading end electrode part laterally protruding from a first side face of the body part, and an internal electrode part provided integrally with the leading end electrode part and positioned at a bottom face of the body part. The printed wiring board has, on a substrate, a first pad and a second pad provided so as to be separated from the first pad. The leading end electrode part is joined to the first pad by soldering and the internal electrode part is joined to the second pad by soldering.

### TECHNICAL FIELD

The present invention relates to a circuit board formed by an electronic component being mounted on a printed wiring board. The present invention relates to a method for mounting the electronic component on the printed wiring board.

### BACKGROUND ART

Patent Literature 1 discloses a configuration in which a MOSFET (metal-oxide-semiconductor field-effect transistor) being an electronic component is mounted on a printed board (printed wiring board) by soldering.

In the configuration of Patent Literature 1, the MOSFET includes: a semiconductor chip; a pad electrode joined to the bottom face of the semiconductor chip and electrically connected thereto; two lead terminals electrically connected to the semiconductor chip; and a having resin an approximately rectangular parallelepiped shape and encapsulating, in a molding, the semiconductor chip. One end portion of the pad electrode protrudes outwardly from one side face of the resin. The two lead terminals are drawn from the other side face of the resin.

On the printed board, three lands (pads) respectively corresponding to the pad electrode and the two lead terminals are formed. On the surfaces of the three lands, a solder paste is printed.

The MOSFET is placed on the printed board such that the bottom face, i.e., an electrode face, of the pad electrode, and the leading end faces of the two lead terminals respectively overlap corresponding lands, and the printed board is heated. The solder paste on the three lands is melted, and the pad electrode and the two lead terminals are soldered to the respectively corresponding lands and joined.

When good soldering has been performed between: the pad electrode and the two lead terminals; and the three lands, a solder fillet having a good (appropriate) shape is formed between the land and the entire periphery of the side face of the one end portion of the pad electrode protruding from the resin, and between each land and the entire periphery of the side face of the leading end portion of the corresponding lead terminal.

### CITATION LIST

### Patent Literature

[PTL 1] Japanese Laid-Open Patent Publication No. 2007-12850

### SUMMARY OF THE INVENTION

### Problems to be Solved by the Invention

In the MOSFET of Patent Literature 1 above, the leading end faces of the two lead terminals are positioned below the electrode face of the pad electrode. Therefore, when the MOSFET is disposed on the printed board, the MOSFET is tilted such that the side of the two lead terminals is raised. Accordingly, the pad electrode is tilted such that the side of the one end portion protruding from the side face of the resin is lowered, and as compared with the interval between the one end portion and the land, the interval between the land and the portion present inside the resin, which is the portion on the side opposite to the one end portion, becomes large.

Different from the MOSFET of Patent Literature 1 above, even when the leading end faces of the two lead terminals are designed to be at the same height position as the electrode face of the pad electrode, a MOSFET in which the leading end faces of the two lead terminals are positioned below the electrode face of the pad electrode may be produced due to variation in manufacture. When such a MOSFET is mounted, a state where the pad electrode is tilted such that the side of the one end portion thereof is lowered may be caused, similar to the above.

When the printed board is heated in the state where the pad electrode is tilted as above, and the solder paste on the land is melted, the solder melted between the one end portion and the land tends to flow on the surface of the land and move to a portion inside the resin where the interval with respect to the land is large. Accordingly, the solder may become insufficient at the one end portion of the pad electrode, and as a result, in the one end portion, a good solder fillet may fail to be formed, resulting in poor soldering.

In view of such a problem, an object of the present invention is to provide a circuit board and an electronic component mounting method with which poor soldering is less likely to occur at an electronic component mounted on a printed wiring board.

### Solution to the Problems

A first aspect of the present invention relates to a circuit board. The circuit board according to the present aspect includes: an electronic component; and a printed wiring board to which the electronic component is mounted by soldering. The electronic component includes a body part having a bottom face and a first side face, and a terminal board disposed at a bottom portion of the body part. The terminal board has a first terminal part laterally protruding from the first side face, and a second terminal part provided integrally with the first terminal part and positioned at the bottom face. The printed wiring board has a substrate covered by a solder resist, a first pad provided on the substrate, and a second pad provided on the substrate so as to be separated from the first pad. The first terminal part is joined to the first pad by soldering, and the second terminal part is joined to the second pad by soldering.

In the circuit board according to the present aspect, a region where the pad is absent is formed between the first pad and the second pad. Therefore, during mounting of the electronic component onto the printed wiring board, the melted solder can be prevented from moving from the first pad side to the second pad side. Accordingly, insufficiency of the solder on the first pad side is less likely to be caused. Therefore, it is possible to prevent occurrence of poor mounting of the electronic component due to failure of formation of a good solder fillet at one end portion of the terminal board due to insufficiency of the solder.

A second aspect of the present invention relates to an electronic component mounting method for mounting an electronic component onto a printed wiring board by soldering. In the mounting method according to the present aspect, the electronic component includes a body part having a bottom face and a first side face, and a terminal board disposed at a bottom portion of the body part. The terminal board has a first terminal part laterally protruding from the first side face, and a second terminal part provided integrally with the first terminal part and positioned at the bottom face. The printed wiring board has a substrate covered by a solder resist, a first pad provided on the substrate, and a second pad provided on the substrate so as to be separated from the first pad. In a mounting step of mounting the electronic component onto the printed wiring board, a first solder paste is placed on the first pad and a second solder paste is placed on the second pad, the electronic component is disposed on the printed wiring board such that the first terminal part is placed on the first solder paste so as to overlap the first pad, and the second terminal part is placed on the second solder paste so as to overlap the second pad, and the printed board is heated and the first solder paste and the second solder paste are melted.

With the electronic component mounting method according to the present aspect, effects similar to those according to the circuit board of the first aspect can be exhibited.

### Advantageous Effects of the Invention

According to the present invention, it is possible to provide a circuit board and an electronic component mounting method with which poor soldering is less likely to occur at an electronic component mounted on a printed wiring board.

The effects and the significance of the present invention will be further clarified by the description of the embodiment below. However, the embodiment below is merely an example for implementing the present invention. The present invention is not limited to the description of the embodiment below in any way.

### BRIEF DESCRIPTION OF THE DRAWINGS

FIG. 1 is a plan view of a circuit board according to an embodiment.

FIG. 2A and FIG. 2B are respectively a plan view and a bottom view of an electronic component according to the embodiment.

FIG. 3A and FIG. 3B are respectively a side view and a cross-sectional view of the electronic component according to the embodiment.

FIG. 4A and FIG. 4B are respectively a plan view and an end view of an electronic component mounting portion, of a printed wiring board, being the vicinity of the portion where the electronic component is mounted, according to the embodiment.

FIG. 5A shows a state where, in the electronic component mounting portion, a first metal foil, a second metal foil, and two third metal foils are disposed on a substrate, according to the embodiment. FIG. 5B shows a solder resist by which the substrate is covered in the electronic component mounting portion, according to the embodiment.

FIG. 6A and FIG. 6B are respectively a plan view and an end view of a main part of the printed wiring board in a state where a first solder paste, a second solder paste, and third solder pastes are respectively placed on a first pad, a second pad, and two third pads, according to the embodiment.

FIG. 7A and FIG. 7B are respectively a plan view and an end view of a main part of the circuit board showing a state before solder pastes are melted after the electronic component has been disposed on the printed wiring board, according to the embodiment.

FIG. 8A and FIG. 8B are respectively a plan view and an end view of a main part of the circuit board showing a state where mounting of the electronic component onto the printed wiring board is completed, according to the embodiment.

FIG. 9A is a plan view showing portions of the pad electrode, the first pad, and the second pad while the printed wiring board having the electronic component disposed thereon is heated, according to the embodiment. FIG. 9B shows a state where the electronic component is disposed so as to be tilted on the printed wiring board according to the embodiment.

FIG. 10A is a plan view of the electronic component mounting portion of the printed wiring board according to Modification 1. FIG. 10B is an end view showing a state where the electronic component is disposed on the printed wiring board according to Modification 1.

FIG. 11A is a plan view of the electronic component mounting portion of the printed wiring board according to Modification 2. FIG. 11B is an end view showing a state where the electronic component is disposed on the printed wiring board according to Modification 2.

FIG. 12A is a plan view of the printed wiring board according to another modification. FIG. 12B is a side view of the electronic component according to another modification.

It is noted that the drawings are solely for description and do not limit the scope of the present invention in any way.

### BEST MODE FOR CARRYING OUT THE INVENTION

Hereinafter, a circuit board will be described with reference to the drawings. For convenience, X-, Y-, and Z-axes orthogonal to each other are indicated in the drawings. The Z-axis direction is the up-down direction of an electronic component 100 and is the direction perpendicular to the surface of a printed wiring board 20.

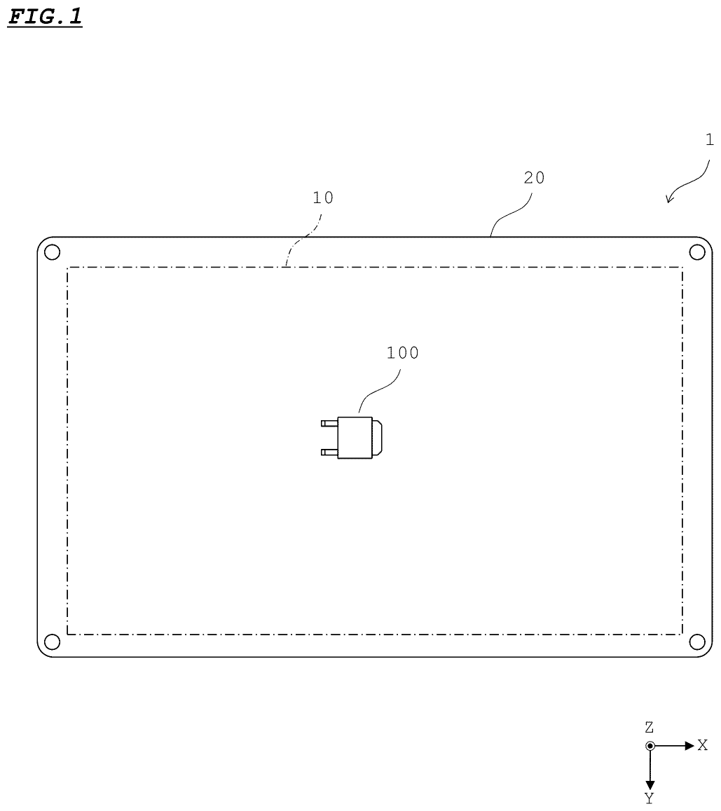

FIG. 1 is a plan view of a circuit board 1.

The circuit board 1 includes: an electronic component group 10 composed of a large number of electronic components; and the printed wiring board 20 on which each electronic component of the electronic component group 10 is mounted by soldering. The printed wiring board 20 has a predetermined shape, e.g., a quadrangular shape. Each electronic component of the electronic component group 10 is electrically connected to pattern wiring (not shown) formed on the printed wiring board 20, whereby an electronic circuit is formed.

The electronic component group 10 mounted on the printed wiring board 20 includes the electronic component 100 of a package type having a heat dissipation function. The electronic component 100 is a MOSFET (metal-oxide-semiconductor field-effect transistor), for example. The electronic component 100 need not necessarily be a MOSFET, and may be a diode, for example.

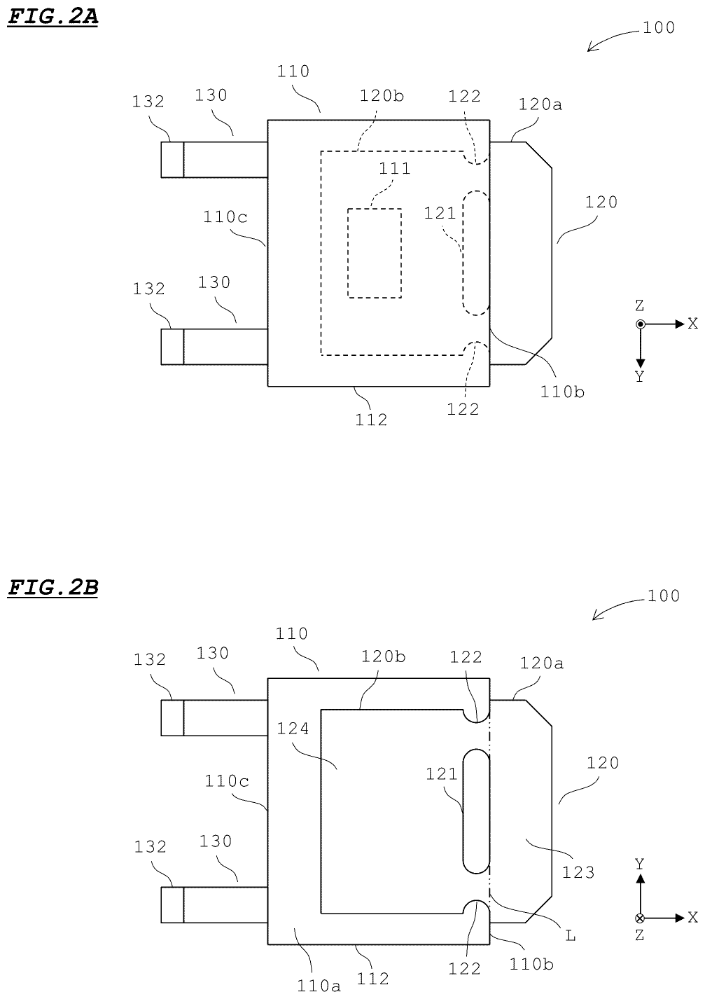

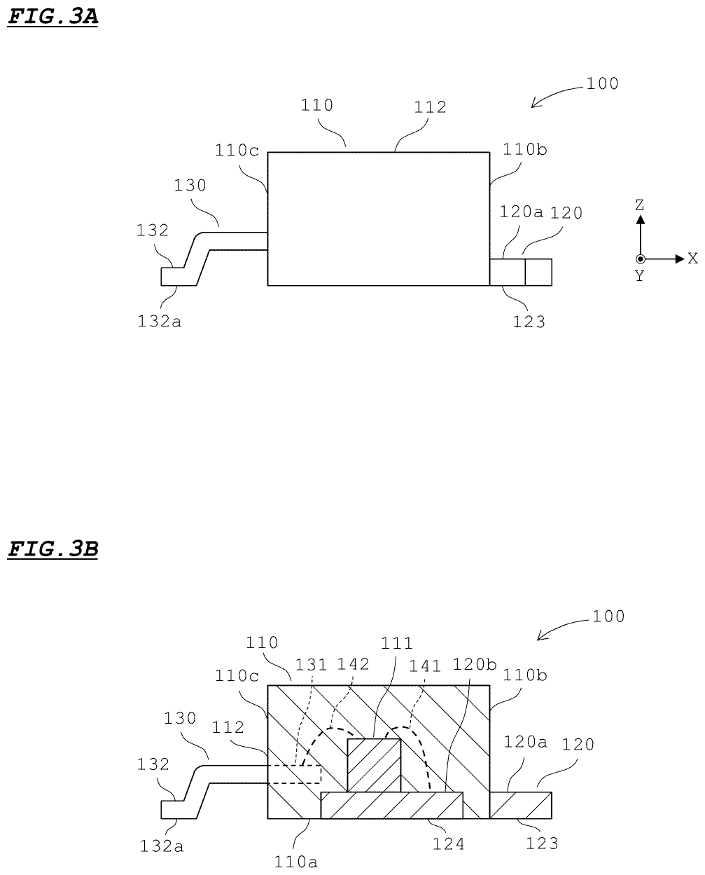

FIG. 2A and FIG. 2B are a plan view and a bottom view of the electronic component 100, respectively. FIG. 3A and FIG. 3B are a side view and a cross-sectional view of the electronic component 100, respectively. In FIG. 3B, the electronic component 100 is cut at the center in the Y-axis direction. In FIG. 2B, a boundary line L between a first terminal face 123 and a second terminal face 124 is indicated by an alternate long and two short dashes line.

The electronic component 100 includes: a body part 110; a pad electrode 120 being a terminal board; and two lead terminals 130.

The body part 110 is composed of a semiconductor chip 111 and a resin-made exterior body 112 covering the semiconductor chip 111. The body part 110 is formed in an approximately rectangular parallelepiped shape, and has a bottom face 110a, a first side face 110b, and a second side face 110c that are in a planar shape. The first side face 110b is oriented in the X-axis positive direction, and the second side face 110c is opposed, back to back, to the first side face 110b.

The pad electrode 120 is a flat plate having a predetermined shape, and is disposed at a bottom portion of the body part 110. The pad electrode 120 includes a leading end electrode part 120a being a first terminal part and an internal electrode part 120b being a second terminal part. The leading end electrode part 120a protrudes from the first side face 110b of the body part 110 in the X-axis positive direction (laterally). The internal electrode part 120b is positioned at the bottom face 110a of the body part 110, and is embedded in the body part 110 such that the bottom face of the internal electrode part 120b is exposed. In the internal electrode part 120b, the bottom face thereof is flush with the bottom face 110a of the body part 110, and the top face of the internal electrode part 120b is in contact with the semiconductor chip 111. Inside the exterior body 112, the internal electrode part 120b is connected to the semiconductor chip 111 via an electric conductor 141. The internal electrode part 120b may slightly protrude from the bottom face 110a of the body part 110.

The leading end electrode part 120a has an approximately quadrangular plate shape whose both corner portions at the leading end are chamfered. The internal electrode part 120b has an approximately quadrangular shape, and has a larger dimension in the X-axis direction and a smaller dimension in the Y-axis direction than the leading end electrode part 120a. In the internal electrode part 120b, in a portion near the boundary with respect to the leading end electrode part 120a, a through-hole 121 that is slender in the Y-axis direction and that penetrates the pad electrode 120 in the thickness direction is formed at a center portion, and cut-out parts 122 are formed at both end portions in the Y-axis direction. A part of the body part 110, i.e., the exterior body 112, is present in the through-hole 121 and the cut-out parts 122. The lower face, of the part of the exterior body 112, present in the through-hole 121 is approximately flush with the bottom face of the internal electrode part 120b.

The bottom face of the leading end electrode part 120a and the bottom face of the internal electrode part 120b serve as the first terminal face 123 and the second terminal face 124, respectively. As shown in FIG. 2B, the line of the first side face 110b of the body part 110 is the boundary line L between the leading end electrode part 120a and the internal electrode part 120b indicated by the alternate long and two short dashes line.

In the present embodiment, the through-hole 121 is formed in the internal electrode part 120b so as to be in contact with the boundary line L, but the through-hole 121 may be formed in the internal electrode part 120b so as to be separated from the boundary line L.

In the pad electrode 120, the leading end electrode part 120a mainly functions as a connection terminal for providing electrical connection to pattern and wiring, the internal electrode part 120b mainly functions as a heat dissipation plate for releasing heat generated at the semiconductor chip 111.

The two lead terminals 130 are drawn in the X-axis negative direction from the second side face 110c of the body part 110. Each lead terminal 130 horizontally extends in the X-axis negative direction, then is bent obliquely downwardly, and further is bent to horizontally extend. Inside the exterior body 112, a base end portion 131 of each lead terminal 130 is connected to the semiconductor chip 111 via an electric conductor 142. A bottom face 132a of a leading end portion 132 of each lead terminal 130 is at a height position equal to that of the bottom face of the pad electrode 120, i.e., the first terminal face 123 and the second terminal face 124.

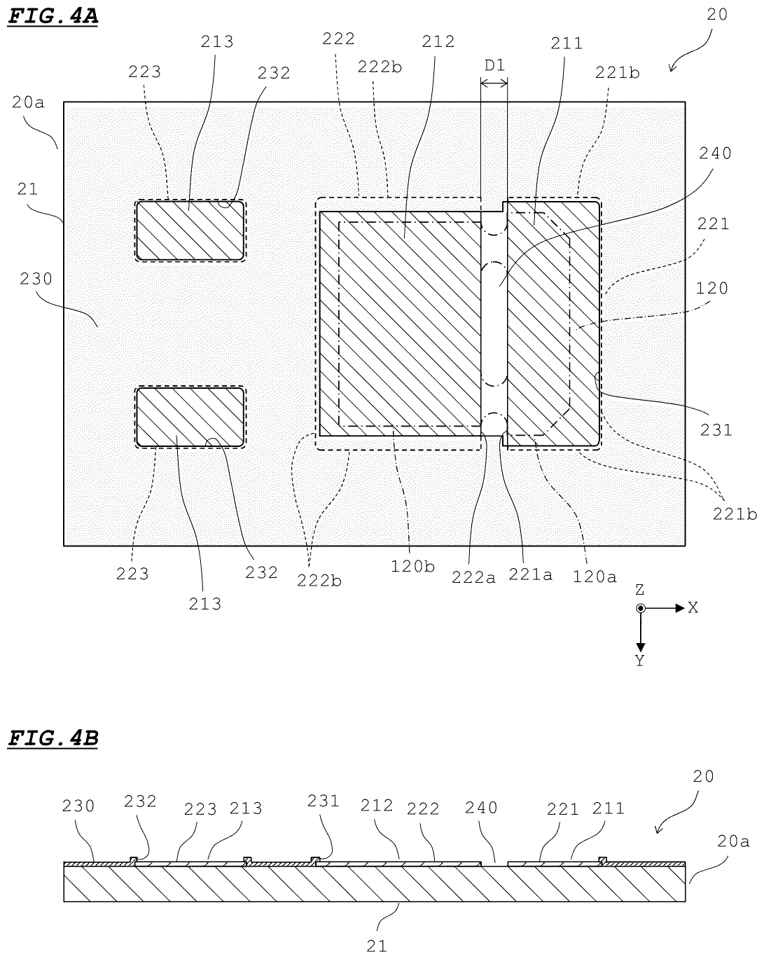

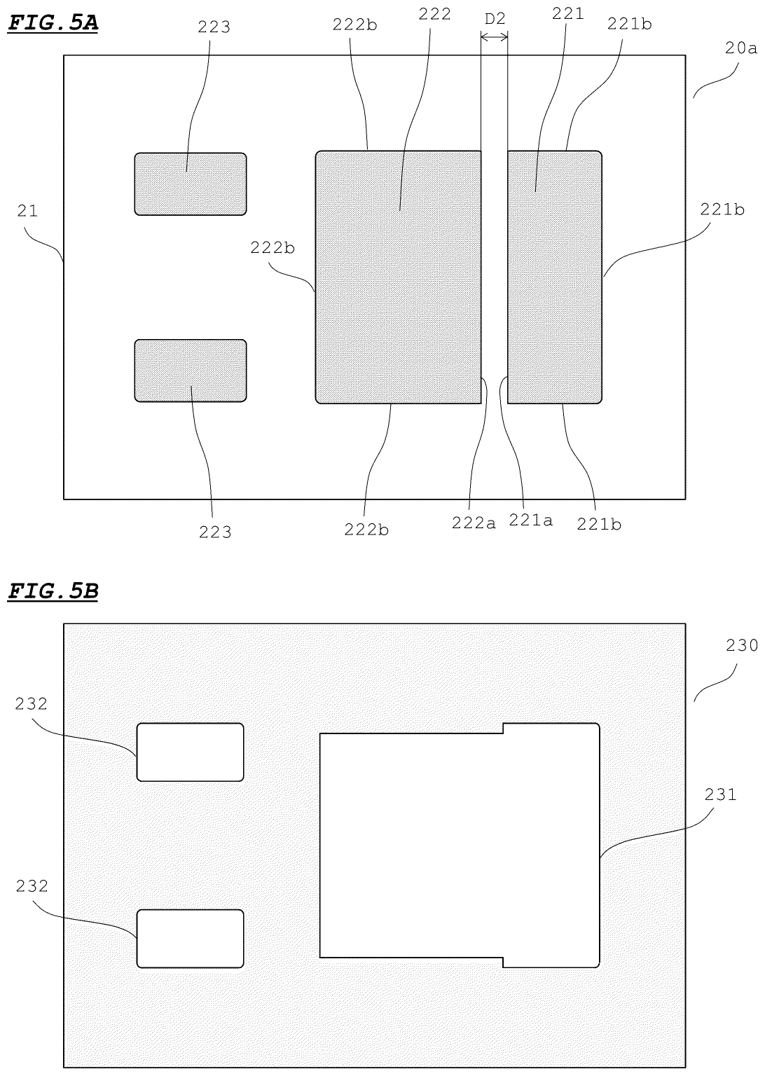

FIG. 4A and FIG. 4B are respectively a plan view and an end view of an electronic component mounting portion 20a, of the printed wiring board 20, being the vicinity of the portion where the electronic component 100 is mounted. FIG. 5A shows a state where, in the electronic component mounting portion 20a, a first metal foil 221, a second metal foil 222, and two third metal foils 223 are disposed on a substrate 21. FIG. 5B shows a solder resist 230 by which the substrate 21 is covered in the electronic component mounting portion 20a. In the end view in FIG. 4B, the electronic component mounting portion 20a is cut at the center in the Y-axis direction of a first pad 211 and a second pad 212.

In FIG. 4A, for convenience, the first pad 211, the second pad 212, and third pads 213 are hatched with oblique lines. In FIG. 4A and FIG. 5B, for convenience, the solder resist 230 is colored with gray. Further, in FIG. 5A, the first metal foil 221, the second metal foil 222, and the third metal foils 223 are colored with gray. Further, in FIG. 4A, for convenience, the pad electrode 120 is indicated by an alternate long and short dash line. Further, in FIG. 4B, for convenience, the thicknesses of the first metal foil 221, the second metal foil 222, the third metal foils 223, and the solder resist 230 are depicted so as to be larger than actual thicknesses with respect to the substrate 21. This also applies to the drawing thereafter as appropriate.

As shown in FIG. 4A and FIG. 4B, as for the printed wiring board 20, in the electronic component mounting portion 20a where the electronic component 100 is mounted, the first pad 211 and the second pad 212 are formed so as to respectively correspond to the leading end electrode part 120a and the internal electrode part 120b of the pad electrode 120, and the two third pads 213 are formed so as to correspond to the two lead terminals 130.

The first pad 211 and the second pad 212 are arranged in the X-axis direction in a state of being separated from each other with a predetermined pad interval D1 provided between these pads. The first pad 211 and the second pad 212 each have an approximately rectangular shape that is long in the Y-axis direction. The first pad 211 has a larger dimension in the Y-axis direction than the second pad 212. The second pad 212 has a larger dimension in the X-axis direction than the first pad 211.

The first pad 211 has a larger dimension in the Y-axis direction than the leading end electrode part 120a, i.e., the first terminal face 123, of the pad electrode 120. The second pad 212 has a larger dimension in the Y-axis direction than the internal electrode part 120b, i.e., the second terminal face 124, of the pad electrode 120. The dimension in the X-axis direction obtained by combining the first pad 211, the second pad 212, and the pad interval D1 is larger than the dimension in the X-axis direction of the pad electrode 120.

The two third pads 213 are arranged in the Y-axis direction at positions separated in the X-axis negative direction from the second pad 212. The pitch between the two third pads 213 is equal to the pitch between the two lead terminals 130. Each third pad 213 has an approximately rectangular shape that is long in the X-axis direction. The dimensions in the X-axis direction and the Y-axis direction of each third pad 213 are larger than the dimensions in the X-axis direction and the Y-axis direction of the bottom face 132a of the leading end portion 132 of each lead terminal 130.

The first pad 211 and the two third pads 213 have respectively corresponding pattern wirings (not shown) connected thereto.

The first pad 211, the second pad 212, and the two third pads 213 are formed on the printed wiring board 20 as described below.

That is, as shown in FIG. 5A, the printed wiring board 20 includes the substrate 21 (raw substrate) formed from a glass epoxy material or the like. On the substrate 21, in the electronic component mounting portion 20a, the first metal foil 221 and the second metal foil 222 each formed of a copper foil or the like are disposed so as to be arranged in the X-axis direction in a state of being separated from each other with a predetermined foil interval D2 provided between these metal foils. In the present embodiment, the foil interval D2 is equal to the pad interval D1. The first metal foil 221 and the second metal foil 222 each have an approximately rectangular shape that is long in the Y-axis direction. The second metal foil 222 has a larger dimension in the X-axis direction than the first metal foil 221. The dimensions in the X-axis direction and the Y-axis direction of the first metal foil 221 and the second metal foil 222 are larger than the dimensions in the X-axis direction and the Y-axis direction of the first pad 211 and the second pad 212, respectively.

Further, on the substrate 21, in the electronic component mounting portion 20a, the two third metal foils 223 formed of a copper foil or the like are disposed so as to be arranged in the Y-axis direction at positions separated in the X-axis negative direction from the second metal foil 222. Each third metal foil 223 has an approximately rectangular shape that is long in the X-axis direction. The dimensions in the X-axis direction and the Y-axis direction of each third metal foil 223 are larger than the dimensions in the X-axis direction and the Y-axis direction of each third pad 213.

The thicknesses of the first metal foil 221, the second metal foil 222, and the third metal foils 223 are about 18 microns, for example.

The substrate 21 is covered by the solder resist 230. As shown in FIG. 5B, in the electronic component mounting portion 20a, the solder resist 230 has, at the positions of the first metal foil 221 and the second metal foil 222, an opening region 231 having a shape corresponding to these metal foils and not covering the substrate 21, and has, at the positions of the two third metal foils 223, two opening regions 232 having shapes corresponding to the third metal foils 223 and not covering the substrate 21. The thickness of the solder resist 230 is about 20 to 30 microns, for example.

As shown in FIG. 4A and FIG. 4B, with respect to the first metal foil 221 and the second metal foil 222, when the opening region 231 of the solder resist 230 is superposed thereon, edges 221a, 222a adjacent to each other out of the four edges of the first metal foil 221 and the second metal foil 222, i.e., out of the entire peripheral edge, are not covered by the solder resist 230, and the other three edges 221b, 222b are covered by the solder resist 230. The regions, not covered by the solder resist 230, of the first metal foil 221 and the second metal foil 222, i.e., regions excluding the portions near the three edges 221b, 222b, serve as the first pad 211 and the second pad 212, respectively.

The edge 221a of the first metal foil 221 extends in a straight line shape in a direction (the Y-axis direction) perpendicular to the direction (the X-axis direction) in which the first pad 211 and the second pad 212 are arranged, and serves as the edge of the first pad 211 adjacent to the second pad 212.

Similarly, with respect to each third metal foil 223, when a corresponding opening region 232 of the solder resist 230 is superposed thereon, the four edges of the third metal foil 223, i.e., the entire peripheral edge, are covered by the solder resist 230. The region, not covered by the solder resist 230, of each third metal foil 223, i.e., a region excluding the portion near the entire peripheral edge, serve as the third pad 213.

The portion of the solder resist 230 covering the three edges 221b, 222b of the first metal foil 221 and the second metal foil 222 becomes higher by the thickness of the first metal foil 221 and the second metal foil 222 than the portion of the solder resist 230 around the first metal foil 221 and the second metal foil 222. The portion of the solder resist 230 covering the entire peripheral edge of each third metal foil 223 becomes higher by the thickness of the third metal foil 223 than the portion of the solder resist 230 around the third metal foil 223.

On the printed wiring board 20, due to the opening region 231 of the solder resist 230, a non-covered region 240 having an approximately slender rectangular shape, which is a region not covered by the solder resist 230, is formed between the first pad 211 and the second pad 212. In the non-covered region 240, not only the solder resist 230 but also the metal foils are absent, the surface of the substrate 21 is exposed, and this surface is lower than the surfaces of the first pad 211 and the second pad 212. Therefore, the non-covered region 240 has a groove shape (groove part) with respect to the first pad 211 and the second pad 212. In the present embodiment, the dimension (width) in the X-axis direction of the non-covered region 240 is equal to the pad interval D1 and the foil interval D2.

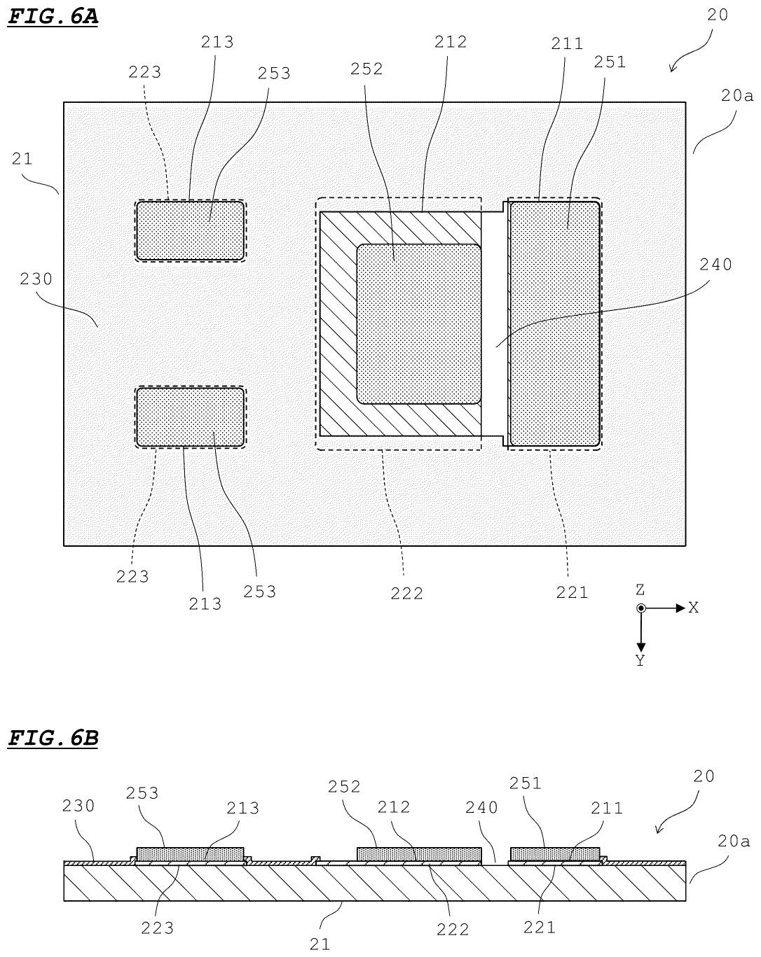

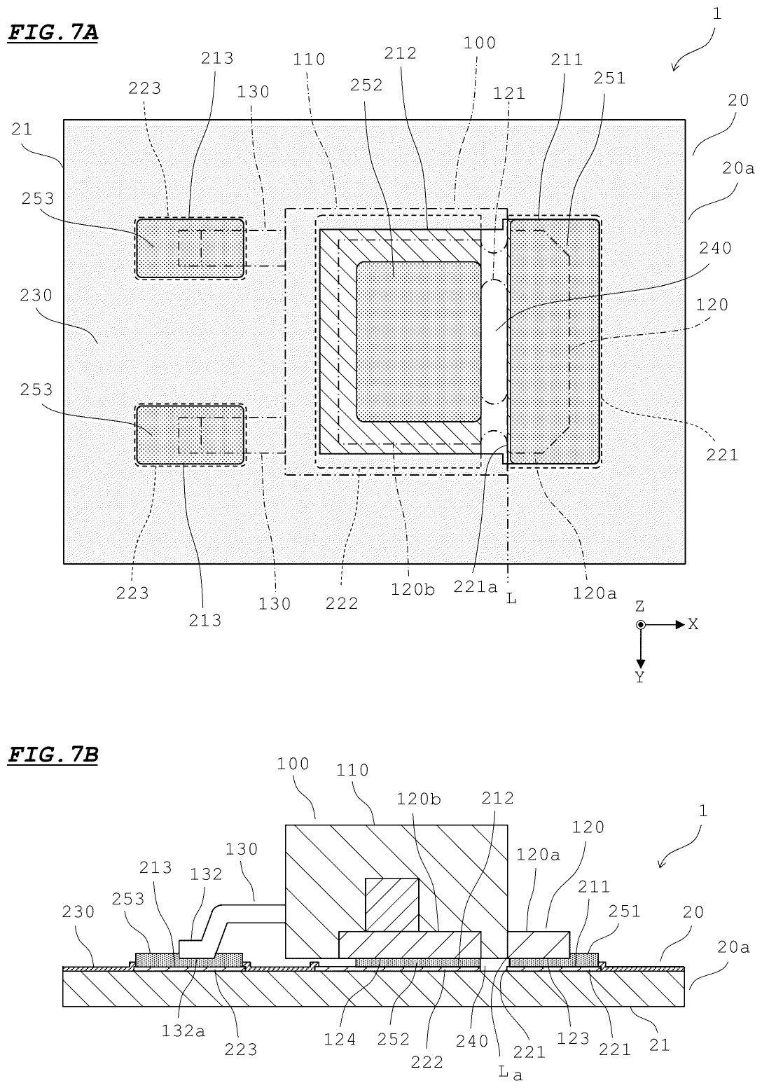

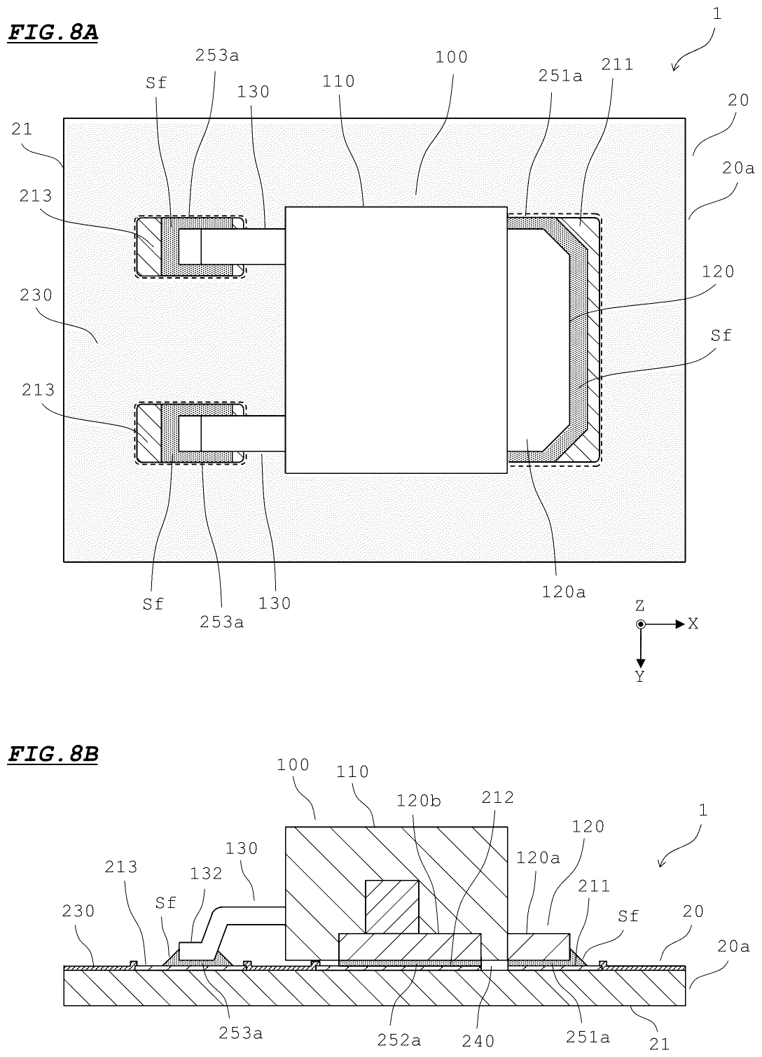

FIG. 6A and FIG. 6B are respectively a plan view and an end view of a main part of the printed wiring board 20 in a state where a first solder paste 251, a second solder paste 252, and third solder pastes 253 are respectively placed on the first pad 211, the second pad 212, and the two third pads 213. FIG. 7A and FIG. 7B are respectively a plan view and an end view of a main part of the circuit board 1 showing a state before the solder pastes 251, 252, 253 are melted after the electronic component 100 has been disposed on the printed wiring board 20. FIG. 8A and FIG. 8B are respectively a plan view and an end view of a main part of the circuit board 1 showing a state where mounting of the electronic component 100 onto the printed wiring board 20 is completed. In FIG. 7A, for convenience, the electronic component 100 is depicted in a transparent state by an alternate long and short dash line.

In FIG. 6A, FIG. 6B, FIG. 7A, and FIG. 7B, for convenience, the first solder paste 251, the second solder paste 252, and the third solder pastes 253 are hatched with a dot pattern. In FIG. 6B and FIG. 7B, for convenience, the thicknesses of the first solder paste 251, the second solder paste 252, and the third solder pastes 253 are depicted so as to be larger than the actual thicknesses with respect to the substrate 21.

When the electronic component 100 is to be mounted on the printed wiring board 20, a mounting step is performed. In this mounting step, mounting onto the printed wiring board 20 of electronic components of the electronic component group 10 other than the electronic component 100 is also performed.

First, as shown in FIG. 6A and FIG. 6B, the first solder paste 251, the second solder paste 252, and the two third solder pastes 253 are respectively placed by printing on the first pad 211, the second pad 212, and the two third pads 213. The thicknesses of the first solder paste 251, the second solder paste 252, and the two third solder pastes 253 are about 150 microns, for example.

The first solder paste 251 and the two third solder pastes 253 respectively have planar sizes approximately equal to those of the first pad 211 and the two third pads 213. Meanwhile, the second solder paste 252 has a planar size significantly smaller than that of the second pad 212. The first solder paste 251 and the second solder paste 252 have an equal thickness, and the area of the first solder paste 251 is larger than the area of the second solder paste 252. Therefore, the amount (volume) of the first solder paste 251 is larger than the amount (volume) of the second solder paste 252.

Next, as shown in FIG. 7A and FIG. 7B, the electronic component 100 is disposed at the mounting position, on the printed wiring board 20, of the electronic component 100 determined in advance. At this time, the leading end electrode part 120a of the pad electrode 120 is placed on the first solder paste 251 so as to overlap the first pad 211. In addition, the internal electrode part 120b of the pad electrode 120 is placed on the second solder paste 252 so as to overlap the second pad 212. Further, the leading end portion 132 of each lead terminal 130 is placed on the third solder paste 253 so as to overlap the third pad 213.

The edge 221a of the first metal foil 221 being the edge, adjacent to the second pad 212, of the first pad 211; and the boundary line L between the leading end electrode part 120a and the internal electrode part 120b match each other in the direction (the X-axis direction) in which the first pad 211 and the second pad 212 are arranged. However, during the mounting, in a range where the mounting position of the electronic component 100 varies, a slight shift may be caused between the edge 221a and the boundary line L. Therefore, that the edge 221a and the boundary line L match each other encompasses that the edge 221a and the boundary line L approximately match each other, taking the above shift into consideration.

When viewed in the Z-axis direction (the up-down direction), the through-hole 121 of the pad electrode 120 overlaps the region between the first pad 211 and the second pad 212, i.e., the non-covered region 240. In the present embodiment, the width, being the pad interval D1, in the X-axis direction of the non-covered region 240 is equal to the diameter in the X-axis direction of the through-hole 121, and the through-hole 121 is in contact with the boundary line L. Therefore, the entirety of the through-hole 121 is accommodated in the non-covered region 240.

Next, the printed wiring board 20 having the electronic component 100 disposed thereon is placed in a reflow oven and heated. The temperature of the printed wiring board 20 becomes high, and the first solder paste 251, the second solder paste 252, and the third solder pastes 253 are melted. Accordingly, the leading end electrode part 120a and the internal electrode part 120b of the pad electrode 120 are respectively soldered to the first pad 211 and the second pad 212 by a first solder 251a, which is the melted first solder paste 251, and a second solder 252a, which is the melted second solder paste 252. In addition, the two lead terminals 130 are soldered to the two third pads 213 by third solders 253a which are the melted third solder pastes 253.

When the printed wiring board 20 has been taken out of the reflow oven and cooled, the first solder 251a, the second solder 252a, and the third solders 253a harden. Accordingly, as shown in FIG. 8A and FIG. 8B, the leading end electrode part 120a and the internal electrode part 120b of the pad electrode 120 are joined to the first pad 211 and the second pad 212 by the first solder 251a and the second solder 252a, respectively. In addition, the two lead terminals 130 are joined to the two third pads 213 by the third solders 253a. Between the first pad 211 and the entire periphery of the side face of the leading end electrode part 120a, and between each third pad 213 and the entire periphery of the side face of the leading end portion 132 of the corresponding lead terminal 130, a skirt-like solder fillet Sf is formed.

In this manner, mounting of the electronic component 100 onto the printed wiring board 20 by soldering is completed. Mounting of the other electronic components of the electronic component group 10 is also completed, whereby the circuit board 1 shown in FIG. 1 is completed.

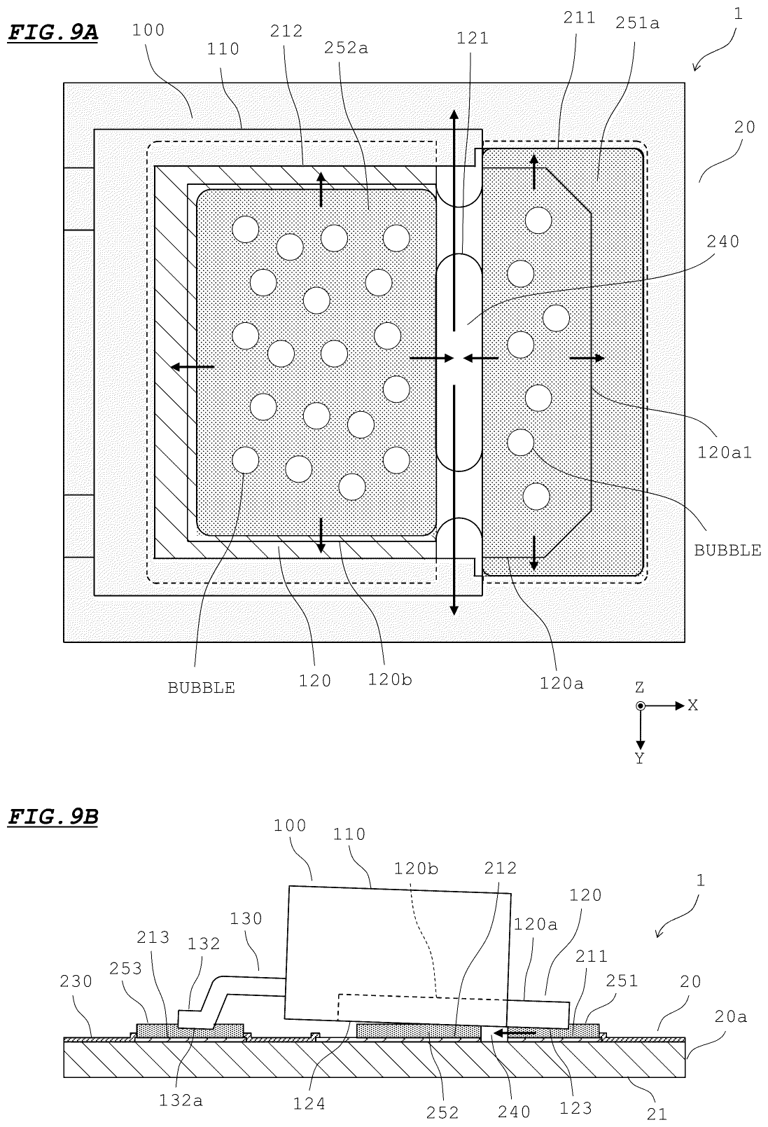

FIG. 9A is a plan view showing the portions of the pad electrode 120, the first pad 211, and the second pad 212 while the printed wiring board 20 having the electronic component 100 disposed thereon is heated. In FIG. 9A, the electronic component 100 is depicted in a transparent state.

When the printed wiring board 20 is heated and the temperature thereof becomes high, the first solder paste 251 and the second solder paste 252 start to be melted at the first pad 211 and the second pad 212.

In the second pad 212, a large pad region remains around the second solder paste 252, and thus, as shown in FIG. 9A, the second solder 252a, which is the melted second solder paste 252, spreads in the second pad 212. The second solder 252a having spread in the second pad 212 does not enter the region, i.e., the non-covered region 240, between the first pad 211 and the second pad 212 where the pad is absent. In the first pad 211 as well, the first solder 251a, which is the melted first solder paste 251, does not enter the non-covered region 240. Accordingly, a gap space due to the absence of the solder is generated between the non-covered region 240 and the bottom face (the second terminal face 124 of the internal electrode part 120b) of the pad electrode 120.

When the first solder paste 251 and the second solder paste 252 start to be melted, air contained in these solder pastes is discharged, and a large number of bubbles are generated between the first solder 251a (the first solder paste 251) and the first terminal face 123, and between the second solder 252a (the second solder paste 252) and the second terminal face 124. These bubbles move in all directions, and escape from between the first solder 251a and the first terminal face 123 and between the second solder 252a and the second terminal face 124. At this time, in the first pad 211, bubbles having moved in the X-axis negative direction escape into the gap space of the non-covered region 240. In addition, in the second pad 212, bubbles having moved in the X-axis positive direction escape into the gap space of the non-covered region 240. The air discharged into the gap space flows in the Y-axis direction in the gap space, to be discharged to the outside of the electronic component 100. Therefore, the amount of bubbles escaping from a side face 120al (hereinafter, referred to as “leading end side face 120al”) oriented in the X-axis positive direction of the leading end electrode part 120a significantly decreases. Accordingly, it is possible to prevent an event in which, since discharge of bubbles from the leading end side face 120al continues even after heating has ended, the solder fillet Sf cannot be formed at the portion, of the leading end side face 120al, from which air is discharged. Therefore, a good solder fillet Sf can be formed between the first pad 211 and the entire periphery of the side face of the leading end electrode part 120a.

Further, since the non-covered region 240 has a groove shape with respect to the first pad 211 and the second pad 212, the gap space due to the non-covered region 240 can be made large, and thus, bubbles can easily escape through the gap space. In addition, the edges 221a, 222a adjacent to each other of the first metal foil 221 and the second metal foil 222 are not covered by the solder resist 230. Thus, the solder resist 230 does not become an obstruction, and bubbles present in the first pad 211 and the second pad 212 easily escape into the gap space. Therefore, bubbles are further less likely to be discharged from the leading end side face 120al, and a still better solder fillet Sf can be formed at the leading end electrode part 120a.

In a configuration in which one pad corresponds to the pad electrode 120 and the gap space of the non-covered region 240 is not formed, bubbles generated at a portion, closer to the second terminal face 124, of the first terminal face 123, and bubbles generated at a portion, closer to the first terminal face 123, of the second terminal face 124 easily escape in the X-axis direction from the leading end side face 120al side of the leading end electrode part 120a. In addition, both sides in the Y-axis direction of the through-hole 121 are filled with the first solder 251a and the second solder 252a having spread from the first terminal face 123 side and the second terminal face 124 side. Therefore, bubbles generated at the second terminal face 124 are easily concentrated in the through-hole 121. This allows easy occurrence of a phenomenon in which large bubbles are generated in the vicinity of the through-hole 121, and these bubbles move to the first terminal face 123 side and escape at once from the leading end side face 120al side of the leading end electrode part 120a. This easily results in an event in which, since discharge of bubbles from the leading end side face 120al continues even after heating has ended, the solder fillet Sf cannot be formed at the portion, of the leading end side face 120al, from which air is discharged.

FIG. 9B shows a state where the electronic component 100 is disposed so as to be tilted on the printed wiring board 20.

In the electronic component 100, due to variation in manufacture, the bottom face 132a of the leading end portion 132 of each of the two lead terminals 130 may be positioned below the bottom face (the first terminal face 123 and the second terminal face 124) of the pad electrode 120. In the mounting step, in a case where such an electronic component 100 is disposed on the printed wiring board 20, if the electronic component 100 is tilted, the pad electrode 120 enters a state of being tilted such that the leading end electrode part 120a side thereof is lowered. Accordingly, the interval between the internal electrode part 120b and the second pad 212 becomes larger than the interval between the leading end electrode part 120a and the first pad 211.

When the printed wiring board 20 is heated in a state where the pad electrode 120 is tilted in this manner and the first solder paste 251 on the first pad 211 is melted, the first solder 251a having been melted between the leading end electrode part 120a and the first pad 211 easily moves, as indicated by the arrow in FIG. 9B, to the internal electrode part 120b side where the interval with respect to the second pad 212 is large.

However, in the printed wiring board 20, a region where the pad is absent, i.e., in the present embodiment, the non-covered region 240, is formed between the first pad 211 and the second pad 212, and thus, the first solder 251a does not flow over the region. Accordingly, the first solder 251a between the leading end electrode part 120a and the first pad 211 is prevented from moving to the second pad 212 side. Therefore, insufficiency of the first solder 251a on the first pad 211 side is less likely to be caused, and thus, a good solder fillet Sf can be formed at the leading end electrode part 120a.

Further, since the amount of the first solder paste 251 is larger than the amount of the second solder paste 252, the amount of the first solder 251a present on the first pad 211 becomes larger than the amount of the second solder 252a present on the second pad 212. Accordingly, insufficiency of the first solder 251a on the first pad 211 side is further less likely to be caused. Therefore, a still better solder fillet Sf can be formed at the leading end electrode part 120a.

### Effects of Embodiment

The circuit board 1 of the present embodiment has been described above. According to the present embodiment, the following effects can be exhibited.

The circuit board 1 includes: the electronic component 100; and the printed wiring board 20 to which the electronic component 100 is mounted by soldering. The electronic component 100 includes: the body part 110 having the bottom face 110a and the first side face 110b; and the pad electrode 120 disposed at a bottom portion of the body part 110. The pad electrode 120 has: the leading end electrode part 120a laterally protruding from the first side face 110b; and the internal electrode part 120b provided integrally with the leading end electrode part 120a and positioned at the bottom face 110a. The printed wiring board 20 has: the substrate 21 covered by the solder resist 230; the first pad 211 provided on the substrate 21; and the second pad 212 provided on the substrate 21 so as to be separated from the first pad 211. The leading end electrode part 120a is joined to the first pad 211 by soldering, and the internal electrode part 120b is joined to the second pad 212 by soldering.

According to this configuration, a region where the pad is absent is formed between the first pad 211 and the second pad 212. Therefore, during mounting of the electronic component 100 onto the printed wiring board 20, the first solder 251a having been melted can be prevented from moving from the first pad 211 side to the second pad 212 side. Accordingly, insufficiency of the first solder 251a is less likely to be caused on the first pad 211 side.

Further, due to the absence of the solder in the region between the first pad 211 and the second pad 212, a gap space is generated below the pad electrode 120. Accordingly, during heating of the printed wiring board 20, bubbles generated between the first solder 251a and the first terminal face 123 and between the second solder 252a and the second terminal face 124 are allowed to escape to the outside of the electronic component 100 through the gap space. Accordingly, the amount of bubbles escaping from the leading end electrode part 120a can be decreased.

Therefore, in the circuit board 1, it is possible to prevent occurrence of poor mounting of the electronic component 100 due to failure of formation of a good solder fillet Sf at the leading end electrode part 120a of the pad electrode 120 due to insufficiency of the solder and discharge of bubbles.

Further, in the circuit board 1, the amount of the first solder paste 251 is made larger than the amount of the second solder paste 252. Therefore, the amount of the first solder 251a present on the first pad 211 is made larger than the amount of the second solder 252a present on the second pad 212. Accordingly, insufficiency of the first solder 251a on the first pad 211 is further less likely to be caused.

Further, in the circuit board 1, the first pad 211 has the edge 221a adjacent to the second pad 212 and extending in a straight line shape in the Y-axis direction perpendicular to the X-axis direction in which the first pad 211 and the second pad 212 are arranged. The edge 221a and the boundary line L between the leading end electrode part 120a and the internal electrode part 120b match each other in the X-axis direction.

According to this configuration, it is possible to cause the first pad 211 to be assuredly present up to the edge on the internal electrode part 120b side of the leading end electrode part 120a and prevent the first pad 211 from extending into the internal electrode part 120b. Therefore, soldering of the leading end electrode part 120a can be performed without waste by the first solder 251a present on the first pad 211.

Further, in the circuit board 1, on the substrate 21, the first metal foil 221 and the second metal foil 222 are disposed in a state of being separated from each other. Regions, not covered by the solder resist 230, of the first metal foil 221 and the second metal foil 222 serve as the first pad 211 and the second pad 212, respectively.

According to this configuration, below the pad electrode 120 between the first pad 211 and the second pad 212, a large gap space is easily formed due to the absence of not only the solder but also the metal foil. Accordingly, bubbles generated between the first solder 251a and the first terminal face 123 and between the second solder 252a and the second terminal face 124 easily escape to the outside of the electronic component 100 through the gap space.

Further, in the circuit board 1, the non-covered region 240 not covered by the solder resist 230 is provided between the first pad 211 and the second pad 212.

According to this configuration, below the pad electrode 120 between the first pad 211 and the second pad 212, a still larger gap space is easily formed due to the absence of the solder resist 230. Accordingly, bubbles still further easily escape to the outside of the electronic component 100 through the gap space.

Further, in the circuit board 1, the edges 221a, 221b adjacent to each other of the first metal foil 221 and the second metal foil 222 are not covered by the solder resist 230.

According to this configuration, the solder resist 230 does not become an obstruction, and bubbles easily escape from between the first solder 251a and the first terminal face 123 and between the second solder 252a and the second terminal face 124, into the gap space.

Further, in the circuit board 1, in the internal electrode part 120b, the through-hole 121 that penetrates the pad electrode 120 in the thickness direction and in which a part of the body part 110 is present is formed. The through-hole 121 overlaps a region between the first pad 211 and the second pad 212.

According to this configuration, bubbles generated between the second solder 252a and the second terminal face 124 are allowed to escape to the outside of the electronic component 100 through the gap space without being concentrated in the through-hole 121.

Although an embodiment of the present invention has been described above, the present invention is not limited to the above embodiment. In addition, application examples of the present invention can also be modified in various ways, in addition to the above embodiment.

### <Modification 1>

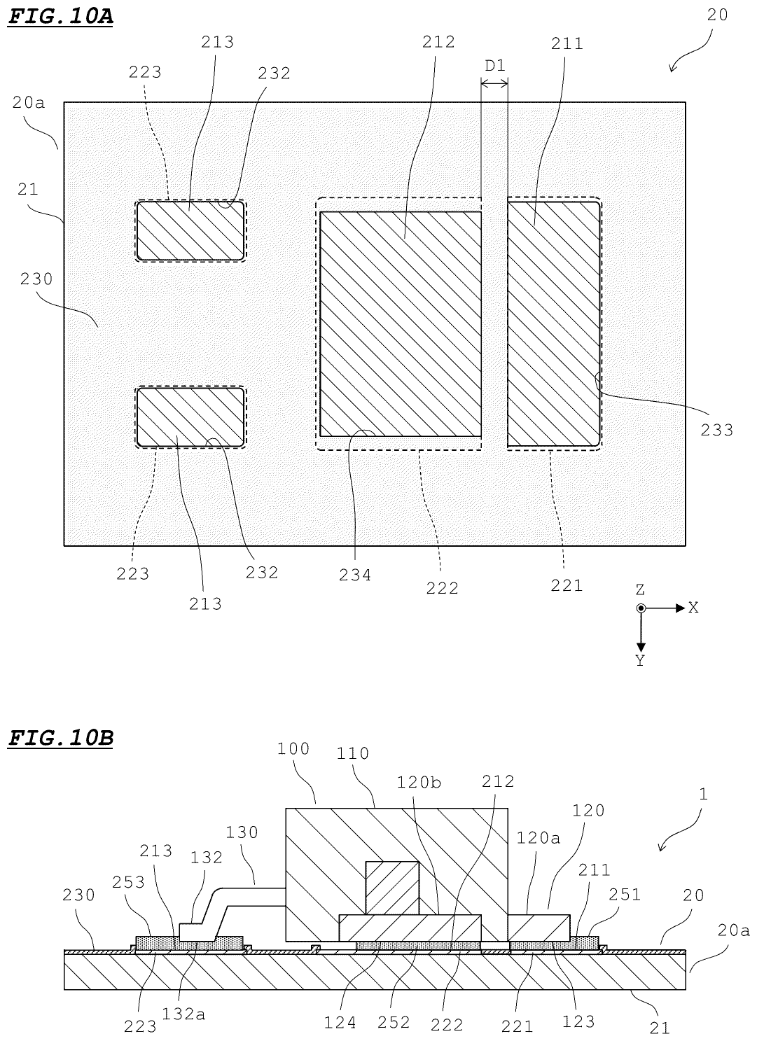

FIG. 10A is a plan view of the electronic component mounting portion 20a of the printed wiring board 20 according to Modification 1. FIG. 10B is an end view showing a state where the electronic component 100 is disposed on the printed wiring board 20 according to Modification 1.

In the present modification, in the printed wiring board 20, the region between the first pad 211 and the second pad 212 is covered by the solder resist 230, and the non-covered region 240 is absent. The solder resist 230 is provided with a first opening region 233 and a second opening region 234 that do not cover the substrate 21. The first opening region 233 and the second opening region 234 respectively have a shape and a size equal to those of the first pad 211 and the second pad 212, and an interval equal to the pad interval D1 is provided between these opening regions.

In the present modification, the surface of the substrate 21 between the first pad 211 and the second pad 212 can be protected by the solder resist 230. However, in a state where the electronic component 100 is disposed on the printed wiring board 20, the gap space generated below the pad electrode 120 between the first pad 211 and the second pad 212 becomes smaller than the gap space of the above embodiment by an amount corresponding to the presence of the solder resist 230. Accordingly, bubbles may become less likely to escape to the outside of the electronic component 100 through the gap space.

### <Modification 2>

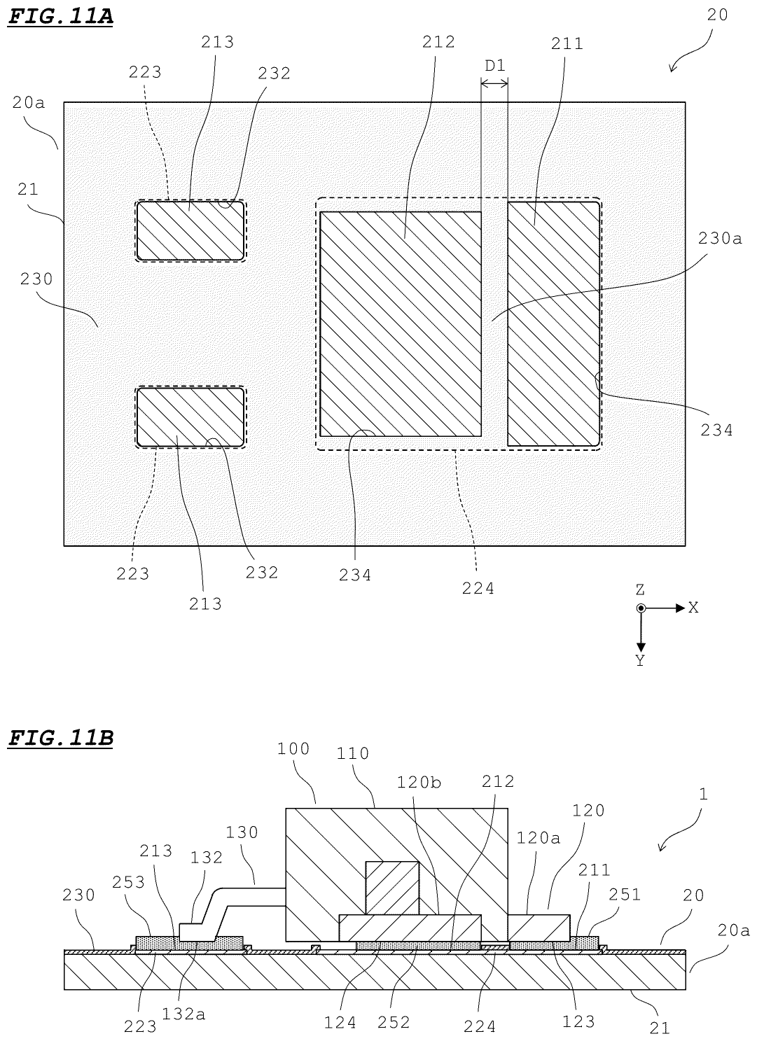

FIG. 11A is a plan view of the electronic component mounting portion 20a of the printed wiring board 20 according to Modification 2. FIG. 11B is an end view showing a state where the electronic component 100 is disposed on the printed wiring board 20 according to Modification 2.

In the present modification, the first pad 211 and the second pad 212 are formed on the printed wiring board 20 as described below.

On the substrate 21, a metal foil 224 formed of a copper foil or the like is disposed in the electronic component mounting portion 20a. The metal foil 224 has an approximately rectangular shape that is long in the X-axis direction. In the electronic component mounting portion 20a, the solder resist 230 has the first opening region 233 and the second opening region 234 similar to those of Modification 1 at the position of the metal foil 224.

When the first opening region 233 and the second opening region 234 of the solder resist 230 are superposed on the metal foil 224, a part of the metal foil 224 is covered by a band-shaped portion 230a of the solder resist 230 formed between the first opening region 233 and the second opening region 234. The band-shaped portion 230a crosses the metal foil 224 in the Y-axis direction, and the first pad 211 and the second pad 212 are formed by the portions of the metal foil 224 on both sides of the band-shaped portion 230a.

In the present modification, the area of the metal foil 224 becomes larger than the area obtained by combining the first metal foil 221 and the second metal foil 222. Therefore, as compared with the above embodiment, heat dissipation through the pad electrode 120 from the electronic component 100 becomes good. However, in a state where the electronic component 100 is disposed on the printed wiring board 20, the gap space generated below the pad electrode 120 between the first pad 211 and the second pad 212 becomes smaller than the gap space of the above embodiment, by an amount corresponding to the presence of the solder resist 230 and the metal foil 224. Accordingly, bubbles may become less likely to escape to the outside of the electronic component 100 through the gap space.

### <Other Modifications>

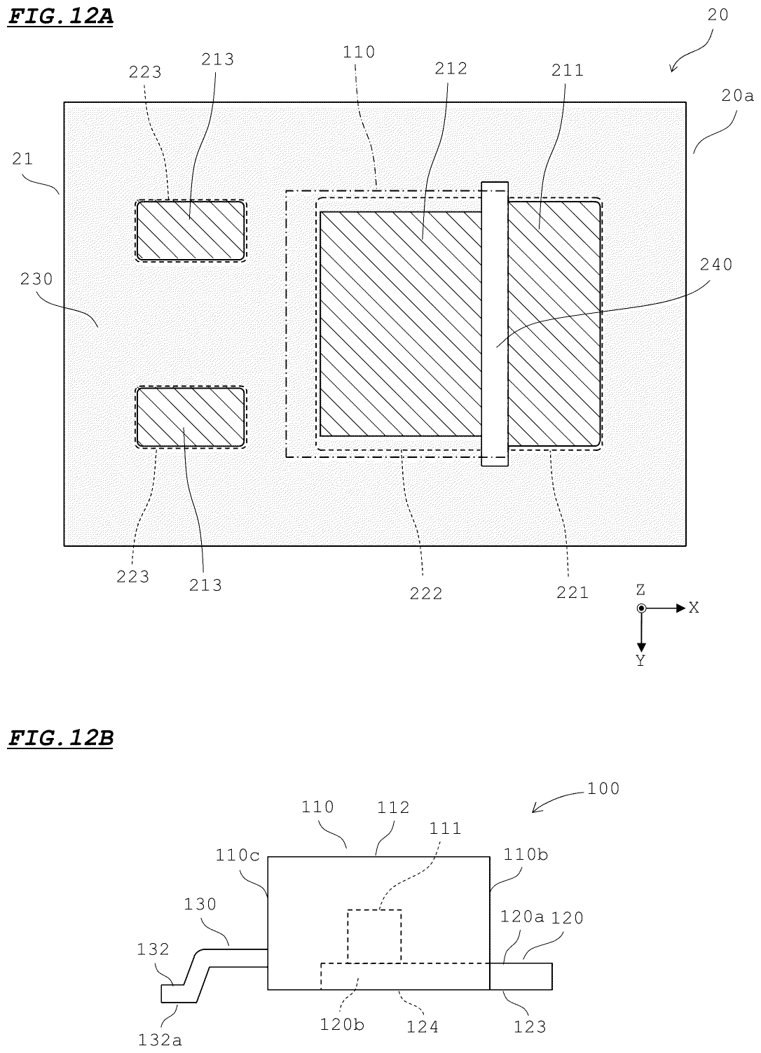

In the above embodiment, the dimension in the Y-axis direction of the non-covered region 240 formed in the printed wiring board 20, i.e., the dimension in the direction perpendicular to the direction in which the first pad 211 and the second pad 212 are arranged, is smaller than the dimension in the same direction of the body part 110 of the electronic component 100. However, as shown in FIG. 12A, the dimension in the Y-axis direction of the non-covered region 240, i.e., the dimension in the direction perpendicular to the direction in which the first pad 211 and the second pad 212 are arranged, may be made larger than the dimension in the same direction of the body part 110 of the electronic component 100, and both end portions of the non-covered region 240 may extend into the outside of the body part 110. With this configuration, the gap space due to the non-covered region 240 can be open to the outside of the body part 110, and thus, bubbles are allowed to further easily escape to the outside of the electronic component 100 through the gap space.

Further, in the above embodiment, in the electronic component 100, the position in the height direction of the bottom face 132a of the leading end portion 132 of each lead terminal 130 is equal to the position in the height direction of the bottom face (the first terminal face 123 and the second terminal face 124) of the pad electrode 120. However, as shown in FIG. 12B, the electronic component 100 may be configured such that the position in the height direction of the bottom face 132a of the leading end portion 132 of each lead terminal 130 is lower than the position in the height direction of the bottom face of the pad electrode 120. In this case, normally, the electronic component 100 is disposed, in a state of being tilted, on the printed wiring board 20. Therefore, during mounting of the electronic component 100 onto the printed wiring board 20, the melted first solder 251a easily moves from the first pad 211 side to the second pad 212 side. Therefore, an effect that insufficiency of the first solder 251a can be less likely to be caused on the first pad 211 side through prevention of movement of the first solder 251a to the second pad 212 side is further more expected.

Further, in the above embodiment, the amount of the first solder 251a present on the first pad 211 is made larger than the amount of the second solder 252a present on the second pad 212. However, the amount of the first solder 251a need not necessarily be made larger than the amount of the second solder 252a.

Further, in the above embodiment, the edge 221a, of the first pad 211, adjacent to the second pad 212 matches the boundary line L between the leading end electrode part 120a and the internal electrode part 120b in the X-axis direction, but need not necessarily match the boundary line L. When the edge 221a of the first pad 211 is positioned on the internal electrode part 120b side with respect to the boundary line L, an end portion of the internal electrode part 120b overlaps the vicinity of the edge 221a of the first pad 211.

Further, in the above embodiment, the pad electrode 120 is provided with the through-hole 121, but the pad electrode 120 need not necessarily be provided with the through-hole 121.

In addition to the above, various modifications can be made as appropriate to the embodiment of the present invention, without departing from the scope of the technological idea defined by the claims.

It is noted that, in claim 3 in the claims, the wording “match” encompasses the concept of “approximately match”.

### INDUSTRIAL APPLICABILITY

The present invention is useful for circuit boards that are used in various types of electronic apparatuses, electric apparatuses, industrial apparatuses, electrical equipment for vehicles, and the like.

### DESCRIPTION OF THE REFERENCE CHARACTERS

1 circuit board
20 printed wiring board
21 substrate
100 electronic component
110 body part
110a bottom face
110b first side face
110c second side face
120 pad electrode (terminal board)
120a leading end electrode part (first terminal part)
120b internal electrode part (second terminal part)
121 through-hole
130 lead terminal
132 leading end portion
132a bottom face
211 first pad
212 second pad
213 third pad
221 first metal foil
221a edge
222 second metal foil
222a edge
223 third metal foil
224 metal foil
230 solder resist
230a band-shaped portion
240 non-covered region
251 first solder paste
251a first solder (solder)
252 second solder paste
252a second solder (solder)
253 third solder paste
253a third solder (solder)
D1 pad interval
D2 foil interval

1. A circuit board comprising:
an electronic component; and
a printed wiring board to which the electronic component is mounted by soldering, wherein
the electronic component includes
a body part having a bottom face and a first side face, and
a terminal board disposed at a bottom portion of the body part,
the terminal board has
a first terminal part laterally protruding from the first side face, and
a second terminal part provided integrally with the first terminal part and positioned at the bottom face,
the printed wiring board has
a substrate covered by a solder resist,
a first pad provided on the substrate, and
a second pad provided on the substrate so as to be separated from the first pad,
the first terminal part is joined to the first pad by soldering, and
the second terminal part is joined to the second pad by soldering.

2. The circuit board according to claim 1, wherein
an amount of a solder present on the first pad is larger than an amount of a solder present on the second pad.

3. The circuit board according to claim 1, wherein
the first pad has an edge adjacent to the second pad and extending in a straight line shape in a direction perpendicular to an arrangement direction in which the first pad and the second pad are arranged, and
the edge and a boundary line between the first terminal part and the second terminal part match each other in the arrangement direction.

4. The circuit board according to claim 1, wherein
on the substrate, a first metal foil and a second metal foil are disposed in a state of being separated from each other, and
regions, not covered by the solder resist, of the first metal foil and the second metal foil serve as the first pad and the second pad, respectively.

5. The circuit board according to claim 4, wherein
a region not covered by the solder resist is provided between the first pad and the second pad.

6. The circuit board according to claim 5, wherein
edges adjacent to each other of the first metal foil and the second metal foil are not covered by the solder resist.

7. The circuit board according to claim 1, wherein
a metal foil is disposed on the substrate,
the solder resist includes a band-shaped portion covering a part of the metal foil so as to cross the metal foil, and
the first pad and the second pad are formed by portions of the metal foil on both sides of the band-shaped portion.

8. The circuit board according to claim 1, wherein
in the second terminal part, a through-hole that penetrates the terminal board in a thickness direction and in which a part of the body part is present is formed, and
the through-hole overlaps a region between the first pad and the second pad.

9. The circuit board according to claim 1, wherein
the body part has a second side face opposed, back to back, to the first side face,
the electronic component further includes a lead terminal drawn from the second side face,
the printed wiring board further includes a third pad to which a leading end portion of the lead terminal is joined by soldering, and
a position in a height direction of a bottom face of the leading end portion of the lead terminal is lower than a position in the height direction of a bottom face of the terminal board.

10. An electronic component mounting method for mounting an electronic component onto a printed wiring board by soldering,
the electronic component including
a body part having a bottom face and a first side face, and
a terminal board disposed at a bottom portion of the body part,
the terminal board having
a first terminal part laterally protruding from the first side face, and
a second terminal part provided integrally with the first terminal part and positioned at the bottom face,
the printed wiring board having
a substrate covered by a solder resist,
a first pad provided on the substrate, and
a second pad provided on the substrate so as to be separated from the first pad, wherein
during a mounting of the electronic component onto the printed wiring board,
a first solder paste is placed on the first pad and a second solder paste is placed on the second pad,
the electronic component is disposed on the printed wiring board such that the first terminal part is placed on the first solder paste so as to overlap the first pad, and the second terminal part is placed on the second solder paste so as to overlap the second pad, and
the printed board is heated and the first solder paste and the second solder paste are melted.

11. The electronic component mounting method according to claim 10, wherein
an amount of the first solder paste is larger than an amount of the second solder paste.

12. The electronic component mounting method according to claim 11, wherein
the first solder paste and the second solder paste have a same thickness,
an area of the first solder paste is larger than an area of the second solder paste, and
during the mounting, the first solder paste and the second solder paste are printed on the first pad and the second pad, respectively.
